(19) United States
(12) Patent Application Publication
(10) Pub. No.: US 2024/0357912 A1
(43) Pub. Date: Oct. 24, 2024

(54) TOUCH DISPLAY PANEL AND TOUCH DISPLAY DEVICE

(71) Applicant: HKC CORPORATION LIMITED, Shenzhen (CN)

(72) Inventors: Jing LI, Shenzhen (CN); Haijiang YUAN, Shenzhen (CN)

(21) Appl. No.: 18/626,410

(22) Filed: Apr. 4, 2024

(30) Foreign Application Priority Data
Apr. 18, 2023 (CN) 202310438343.5

(51) Int. Cl. H10K 59/80; H10K 59/122; H10K 59/40

(52) U.S. Cl. CPC H10K 59/8791; H10K 59/122; H10K 59/40; H10K 59/80517

(57) ABSTRACT

A touch display panel includes a substrate with a touch anti-view area. The touch anti-view area is provided with an anti-view sub-pixel including an anti-view anode, an anti-view light-emitting part and an anti-view cathode; an insulating barrier part formed on a side of the anti-view anode with a first via hole, a part of the anti-view anode being exposed though the first via hole, and a gap is formed between the first via hole and the anti-view cathode; and a touch electrode layer including a first electrode and a second electrode, where the second electrode includes a main electrode part and a connecting part, the connecting part of each second electrode is located in the first via hole and connected with the anti-view anode, and two adjacent second electrodes in the first direction are electrically connected through the anti-view anode.

### CROSS-REFERENCE TO RELATED APPLICATIONS

This application claims priority to Chinese Patent Application No. 202310438343.5, filed Apr. 18, 2023, the entire disclosure of which is incorporated herein by reference.

### TECHNICAL FIELD

The present application pertains to the field of display technologies, more particularly, to a touch display panel and a touch display device.

### BACKGROUND

A touch display device is a device capable of implementing both display and touch control. At present, the touch display device typically includes a touch display panel, which usually includes a display panel and a touch panel. According to a position relationship of the touch panel relative to the display panel, the touch display panel can be divided into a built-in touch display panel and an out-cell touch display panel, where the built-in touch display panel can further be divided into an in-cell touch display panel and an on-cell touch display panel. Since the in-cell touch display panel is convenient for manufacturing thin and light products, it has been widely studied and applied.

The touch display panel generally can be divided into resistive touch display panel, capacitive touch display panel, optical touch display panel and so on according to the working principle of the touch sensing unit, where the touch display panel using a capacitive touch sensing unit can implement multi-point control and has a high sensitivity, which is widely used in the industry. At present, the capacitive touch display panel requires a high number of photomasks and manufacturing processes which leads to the increase of production cost.

### SUMMARY

There are provided a touch display panel and a touch display device according to embodiments of the present disclosure. The technical solution is as below:

According to a first aspect of embodiments of the present disclosure, there is provided a touch display panel, the touch display panel includes a substrate, the substrate is provided with a touch anti-view area, and the touch anti-view area is provided with:
an anti-view sub-pixel including an anti-view anode, an anti-view light-emitting part and an anti-view cathode stacked sequentially;
an insulating barrier part formed on a side of the anti-view anode away from the substrate, wherein the insulating barrier part is provided with a first via hole, a part of the anti-view anode is exposed though the first via hole, and a gap is formed between the first via hole and the anti-view cathode; and
a touch electrode layer including a first electrode and a second electrode alternately arranged in a first direction and insulated from each other, wherein the second electrode includes a main electrode part and a connecting part, the main electrode part of the second electrode and the first electrode are formed on a side of the anti-view sub-pixel away from the substrate and on a side of the insulating barrier part away from the substrate, the connecting part of each second electrode is located in the first via hole and connected with the anti-view anode, and two adjacent second electrodes in the first direction are electrically connected through the anti-view anode.

According to a second aspect of embodiments of the present disclosure, there is provided a display device, which includes a flexible printed circuit board and the touch display panel according to any one of the above, the flexible printed circuit board is electrically connected to a first electrode and a second electrode.

It should be understood that the above general description and the following detailed description are exemplary and explanatory only and are not intended to limit the present application.

### BRIEF DESCRIPTION OF DRAWINGS

The accompanying drawings, which are incorporated in and constitute a part of the description, illustrate embodiments consistent with the present application and, together with the description, serve to explain the principles of the present application. It will be apparent that the drawings described below are only some embodiments of the present application, and other drawings may be obtained from them without creative effort for those of ordinary skill in the art.

FIG. 1 is a sectional structural view of a touch display panel with an insulating barrier part provided in Embodiment I or Embodiment II of the present application.

FIG. 2 is a sectional structural view of an touch display panel with another insulating barrier part provided in Embodiment I or Embodiment II of the present application.

FIG. 3 is a schematic structural view of a display element and an anti-view sub-pixel provided in Embodiment I or Embodiment II of the present application.

FIG. 4 is a schematic structural view of a second electrode being connected to an anti-view anode through a first via hole provided in Embodiment I or Embodiment II of the present application.

FIG. 5 is a top view of the insulating barrier part provided in Embodiment I or Embodiment II of the present application.

FIG. 6 is a top view of the another insulating barrier part provided in Embodiment I or Embodiment II of the present application.

FIG. 7 is a schematic structural view showing that first and second electrodes are connected to the flexible printed circuit board provided in Embodiment I or Embodiment II of the present application.

### DESCRIPTION OF THE EMBODIMENTS

The exemplary embodiments will now be described more fully with reference to the accompanying drawings. However, the example embodiments can be implemented in a variety of forms and should not be construed as being limited to the examples set forth herein. Rather, these embodiments are provided so that the present application will be more comprehensive and complete, and the concept of exemplary embodiments will be fully communicated to those skilled in the art.

In the present application, the terms “first”, “second” are for descriptive purposes only and cannot be construed as indicating or implying relative importance or implying the number of the indicated technical features. Thus, features defined with “first” and “second” may explicitly or implicitly include one or more of the features. In the description of the present application, “multiple” means two or more unless otherwise expressly specified.

In the present application, unless otherwise explicitly provided and limited, the terms such as “mount,” “connect,” should be understood broadly, which, for example, may refer to a fixed connection, a detachable connection, or an integral connection; which may refer to a mechanical connection or an electrical connection; which may refer to a direct connection or an indirect connection via an intermediate medium; which may also refer to a communication between the insides of two elements. For those ordinarily skilled in the art, the specific meanings of the above terms in the present application will be understood according to the specific circumstances.

Further, the described features, structures or characteristics may be incorporated in any suitable manner in one or more embodiments. In the following description many specific details are provided to give a full understanding of the embodiments of the present application. However, those skilled in the art will appreciate that the technical aspects of the present application may be practiced without one or more of the specific details, or other methods, components, devices, steps and the like may be employed. In other instances, the common methods, devices, implementations or operations are not shown or described in detail to avoid obscuring aspects of the present application.

### Embodiment I

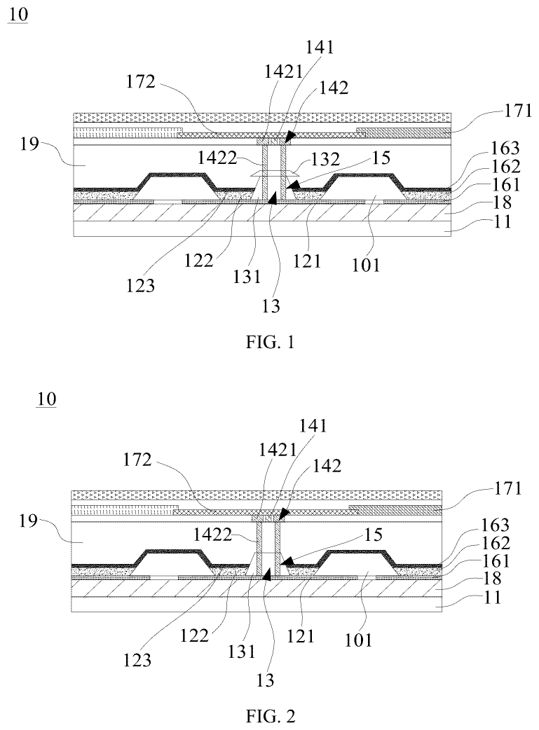

Referring to FIG. 1 or FIG. 2, Embodiment I of the present application provides a touch display panel 10, which includes a substrate 11. The substrate 11 may be a rigid substrate made of glass, but is not limited thereto, or a flexible substrate made of polyimide (PI) or other materials, that is, the touch display panel 10 of the present application is not limited to a rigid non-bendable panel, but may also be a flexible bendable panel.

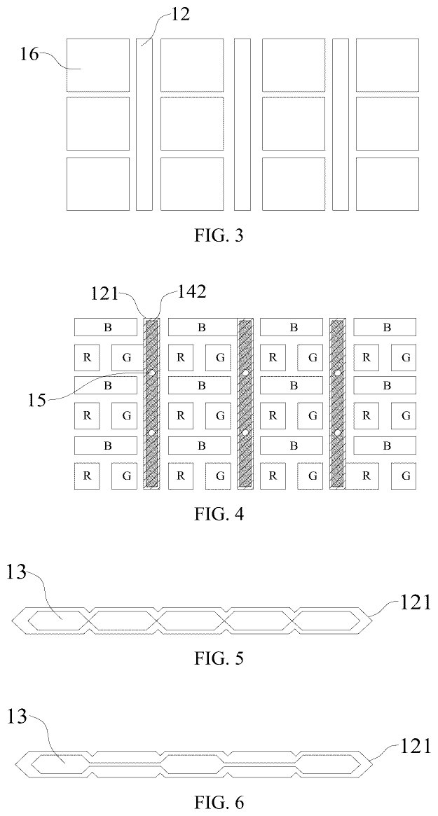

Referring to FIG. 1, FIG. 2 or FIG. 3, the substrate 11 is provided with a touch anti-view area, and the touch anti-view area is provided with an anti-view sub-pixel 12, an insulating barrier part 13 and a touch electrode layer. The touch electrode layer includes first electrodes 141 and second electrodes 142 which are alternately arranged in a first direction and insulated from each other. The second electrode 142 is connected with an anti-view anode 121 in the anti-view sub-pixel 12 through a first via hole 15 on the insulating barrier part 13 to connect adjacent second electrodes 142 to achieve the touch function. That is, the anti-view anode 121 acts as a bridging metal layer to electrically connect the adjacent second electrodes 142, thereby reducing the design of the bridging metal layer, reducing the number of photomasks and manufacturing processes and reducing the production cost of the touch display panel 10.

In the embodiments of the present application, as shown in FIG. 1, FIG. 2 or FIG. 3, the substrate 11 is further provided with display pixel areas 16, the display pixel areas 16 are arranged in an array on the substrate, each of the display pixel areas 16 is provided with a plurality of display sub-pixels arranged spacing from each other, each display sub-pixel includes a display anode 161, a display light-emitting part 162 and a display cathode 163 stacked in sequence, the display anode 161 can release holes to the display light-emitting part 162 under the driving of an external driving voltage, and the display cathode 163 can also release electrons to the display light-emitting part 162 under the driving of the external driving voltage, the electrons and holes combine in the display light-emitting part 162 to produce exciton. The exciton generated in the display light-emitting part 162 can enable the organic molecules in the display light-emitting part 162 to be activated, thereby causing the outermost electrons of the organic molecules to transition from the ground state to the excited state. Since the electrons in the excited state are extremely unstable, they will transition to the ground state, and during the transition, energy will be released in the form of light, thus causing the display light-emitting part 162 to emit light.

The display light-emitting part 162 in different display sub-pixels may emit light of the same color, and is converted into the corresponding color by the quantum dot material or the color resistance element 171 on the color resistance layer.

In the embodiments of the present application, each display pixel area 16 includes red, green and blue display sub-pixels arranged spacing from each other, and the red, green and blue display sub-pixels may emit red, green and blue light, respectively.

In some embodiments, each display pixel area 16 may include four or more display sub-pixels arranged spacing from each other and emitting different-color of lights, which may be specifically designed according to different embodiments.

In order to more conveniently switch between a wide viewing angle and a narrow viewing angle, an anti-view sub-pixel 12 is provided between adjacent display pixel areas 16. The anti-view sub-pixel 12 includes an anti-view anode 121, an anti-view light-emitting part 122 and an anti-view cathode 123 stacked in sequence. The light-emitting principle of the anti-view light-emitting part 122 is the same as that of the display light-emitting part 162, namely, the anti-view anode 121 can release holes to the anti-view light-emitting part 122 under the driving of an external driving voltage, and the anti-view cathode 123 can also release electrons to the anti-view light-emitting part 122 under the driving of the external driving voltage. The electrons and holes combine in the anti-view light-emitting part 122 to generate exciton. The exciton generated in the display light-emitting part 122 can enable the organic molecules in the display light-emitting part 122 to be activated, thereby causing the outermost electrons of the organic molecules to transition from the ground state to the excited state. Since the electrons in the excited state are extremely unstable, they will transition to the ground state, and during the transition, energy will be released in the form of light, thus causing the display light-emitting part 122 to emit light.

It should be noted that the color of the light emitted by the display light-emitting part 162 of different display sub-pixels may be the same, and the color of the light emitted by the display light-emitting part 162 may be the same as that of the anti-view light-emitting part 122, and may be converted into the corresponding color by the quantum dot material above the substrate 11 or the color resistance element 171. For example, both the display light-emitting part 162 and the anti-view light-emitting part 122 emit blue light, the blue light passes upward through the red quantum dot material to emit red light, the blue light passes downward through the green quantum dot material to emit green light, and the blue light does not pass through any quantum dot material to emit blue light, and the quantum dot material corresponding to the anti-view sub-pixel 12 is different in color from the quantum dot materials corresponding to the adjacent two display sub-pixels, so that the anti-view function can be achieved. The blue light passes upward through the red color block element 171 to emit red light, the blue light passes upward through the green color block element 171 to emit green light, and the blue light passes upward through the blue color block element 171 to emit blue light.

In addition, in order to prevent the light emitted by the anti-view light-emitting part 122 from affecting the information reading in the front viewing angle, a light-shielding element 172 is provided at a position corresponding to the anti-view light-emitting part 122, and an orthographic projection of the light-shielding element 172 on the substrate 11 covers an orthographic projection of the anti-view anode 121 on the substrate 11, so as to better implement light-shielding, avoid light leakage of the anti-view pixel in the front viewing angle and ensure normal information reading in the front viewing angle. The light-shielding element 172 may be made of a black matrix (BM) or a black light-opaque material.

Referring to FIG. 1, FIG. 2 or FIG. 4, in the embodiments of the present application, the color of the light emitted by the anti-view light-emitting part 122 may be the same as that emitted by the display light-emitting part 162, and the touch display panel 10 is provided with a color resistance layer on the substrate 11, the color resistance layer includes a color resistance element 171 and a light-shielding element 172, and the color resistance element 171 corresponds to the display anode 161 of the display sub-pixel. The color resistance element 171 includes a red color resistance element 171, a green color resistance element 171, and a blue color resistance element 171, and the light emitted by the display light-emitting element 162 enters the corresponding color resistance element 171 to emit light of a corresponding color.

In the embodiments of the present application, the light emitted by the anti-view sub-pixel 12 is different in color from the adjacent display sub-pixel, so as to mix the light emitted by the adjacent display sub-pixels and interfere with information reading, thereby realizing a narrow viewing angle (anti-view) mode.

When the anti-view function is enabled, the anti-view anode 121 and the anti-view cathode 123 respectively release holes and electrons to the anti-view light-emitting part 122, so that the anti-view light-emitting part 122 emits light. Since the light emitted by the anti-view sub-pixel 12 is different in color from the light emitted by the adjacent display sub-pixel, the light emitted by the anti-view light-emitting part 122 can be mixed with the light emitted by the display sub-pixel at a large viewing angle, interfering with the information reading at the large viewing angle, resulting abnormal in the information reading at the large viewing angle. Moreover, since the light-shielding element 172 is provided above the anti-view anode 121 in the front viewing angle, the light emitted by the anti-view sub-pixel 12 in the front viewing angle cannot be mixed with the light emitted by the display sub-pixel, thus ensuring information reading in the front viewing angle, and thereby implementing the narrow viewing angle mode.

When the anti-view function is disabled, the anti-view sub-pixel 12 does not emit light and does not mix the light emitted by the display sub-pixel, thus ensuring normal information reading at the large viewing angle, and further achieving the wide viewing angle mode.

It is worth mentioning that one anti-view sub-pixel 12 may be provided in each display pixel area 16 to implement the anti-view function. Alternatively, the display pixel areas 16 in a column or row direction share one anti-view sub-pixel 12, that is, the anti-view sub-pixel 12 is provided extending in the row or column direction.

Further, as shown in FIG. 1 or FIG. 2, in order to drive the anti-view anode 121 and the display anode 161, the touch display panel 10 further includes a drive backplane 18, the drive backplane 18 is disposed on the substrate 11, and the display anode 161 is connected to the source or drain of a thin film transistor on the drive backplane 18 through an opening to drive the display anode 161.

It should be noted that the anti-view anode 121 and the display anode 161 can be driven separately, that is, the anti-view anode 121 and the display anode 161 can be driven independently of each other. The anti-view anode 121 may also be connected to one display anode 161 such that the anti-view anode 121 is driven simultaneously with the display anode 161 to which it is connected.

In addition, the anti-view anode 121 and the display anode 161 may be indium tin oxide (ITO), indium zinc oxide (IZO), zinc oxide (ZnO) or indium oxide (In₂O₃).

In the embodiments of the present application, the display pixel areas 16 in a column share one anti-view sub-pixel 12, and the anti-view anode 121 of the anti-view sub-pixel 12 is connected to the display anode 161 of one display sub-pixel in one display pixel area 16, which can emit light together with the display anode 161. The anti-view anodes 121 of adjacent columns are connected to different display anodes 161, for example, the anti-view anodes 121 of the first column are connected to the display anodes 161 of the red sub-pixels, the anti-view anodes 121 of the second column are connected to the display anodes 161 of the green sub-pixels, and the anti-view anodes 121 of the third column are connected to the display anodes 161 of the blue sub-pixels. By connecting the anti-view anode 121 to the display anode 161, it is possible to reduce the number of the anode holes and reduce the loss of aperture ratio.

In addition, the anti-view cathode 123 may be designed over the entire surface, to reduce the number of photomasks, thereby reducing production costs.

The touch electrode layer includes first electrodes 141 and second electrodes 142 which are alternately arranged in a first direction and are insulated from each other. The first electrodes 141 separate the second electrodes 142 from each other. In order to communicate the adjacent second electrodes 142, the anti-view anode 121 is used to communicate the adjacent second electrodes 142, thus reducing the design of bridging metal layers in the prior art, reducing the number of photomasks and manufacturing processes and further reducing the production cost.

It should be noted that one of the first electrode 141 and the second electrode 142 is an induction electrode (Rx), and the other is a drive electrode (Tx).

Further, the first direction may be the same as the extension direction of the anti-view sub-pixel 12, that is, the first direction is the column direction.

In the embodiments of the present application, the first electrode 141 is an induction electrode (Rx), and the second electrode 142 is a drive electrode (Tx). The second electrode 142 includes a main electrode part 1421 and a connecting part 1422. The main electrode part 1421 and the first electrode 141 of the second electrode 142 are formed on the side of the anti-view sub-pixel 12 away from the substrate 11. The connecting part 1422 of each second electrode 142 is located in one first via hole 15 and connected to the anti-view anode 121. Two adjacent second electrodes 142 in the first direction are electrically connected through the anti-view anode 121 to communicate the second electrodes 142 in the first direction.

By using the anti-view anode 121 as a metal layer for bridging the second electrode 142, the metal layer is reduced in overall design of the touch display panel 10, which reduces the number of photomasks and manufacturing processes, and thereby reduces the production cost of the touch display panel 10.

It should be noted that, as shown in FIG. 4, the orthographic projection of the driving electrode (Tx) on the substrate 11 is located within the orthographic projection of the anti-view anode 121 on the substrate 11, so as to ensure that adjacent driving electrodes (Tx) can be connected by the anti-view anode 121. A size of a signal line of the drive electrode (Tx) can be adjusted according to the anti-view function of the anti-view anode 121, so as to adjust the signal quantity.

It is worth mentioning that since the front viewing angle of the anti-view light-emitting part 122 is blocked by the light-shielding element 172, the front viewing angle is not affected when the anti-view light-emitting part 122 is illuminated, and the anti-view anode 121 is connected with the display anode 161, therefore, the touch signal can be driven simultaneously with the display signal without time-sharing, and the touch power consumption and brightness loss caused by time-sharing are reduced.

Referring to FIG. 1 or FIG. 2, in the embodiments of the present application, the touch display panel 10 further includes an encapsulation layer 19, the encapsulation layer 19 may be a TFE (Thin Film Encapsulation 19) disposed on a side of the anti-view cathode 123 away from the substrate 11.

In the embodiments of the present application, the touch electrode layer is located at the uppermost layer of the encapsulation layer 19 to ensure the protection of the OLED package during the manufacturing process.

In some embodiments, the touch electrode layer may also be located in the encapsulation layer 19, and the specific design location may be selected according to different embodiments.

Referring to FIG. 1, FIG. 2, FIG. 5 or FIG. 6, in order to remove the shielding effect of the anti-view cathode 123 and ensure that the adjacent second electrodes 142 can be electrically connected through the anti-view anode 121, an insulating barrier part 13 is arranged on the side of the anti-view anode 121 away from the substrate 11. The insulating barrier part 13 is provided with a first via hole 15, and a part of the anti-view anode 121 is exposed through the first via hole 15. The connecting part 1422 in the second electrode 142 is overlapped with the anti-view anode 121 through the first via hole 15, so as to electrically connect the adjacent second electrodes 142, thereby reducing the design of metal layers, the anti-view anode 121 is multiplexed as a bridging metal layer of the second electrodes 142, which reduces the number of photomasks and manufacturing processes and further reduces the production cost. In addition, there is a gap between the first via hole 15 and the anti-view anode 121, which can remove the blocking influence of the anti-view cathode 123 on the touch signal.

In the embodiments of the present application, referring to FIG. 1 or FIG. 2, the touch display panel 10 further includes a pixel define layer 101, and the pixel define layer 101 is formed on the substrate 11 and located on a side of the anti-view anode 121 away from the substrate 11. In the touch anti-view area, the pixel define layer 101 has an anti-view opening to expose the anti-view anode 121, the insulating barrier part 13 is located in the anti-view opening, and the anti-view light-emitting part 122 and the anti-view cathode 123 are both arranged around the barrier, and the anti-view cathode 123 and the anti-view light-emitting part 122 are both provided with second via holes for the insulating barrier part 13 to pass through, so as to disconnect the anti-view cathode 123 and the anti-view light-emitting part 122, thereby removing the blocking influence of the anti-view cathode 123 and the anti-view light-emitting part 122 on the signal of the second electrode 142.

Furthermore, the insulating barrier part 13 is provided at an intermediate position between the anti-view light-emitting part 122 and the anti-view anode 121, thereby ensuring the anti-view function without affecting the light emission from the anti-view light-emitting part 122.

It is worth mentioning that the first through hole 15 and the second through hole may be vertical through holes or oblique through holes, which are not specifically limited herein.

In some embodiments, both the anti-view cathode 123 and the anti-view light-emitting part 122 may be discontinuously arranged, and the anti-view cathode 123 and the anti-view light-emitting part 122 each are separated into two parts by the insulating barrier part 13, thereby removing the blocking effect of the anti-view cathode 123 on the signal of the second electrode 142.

In some embodiments, the insulating barrier part 13 may be disposed on the same layer as the pixel define layer 101, so as to reduce the number of photomasks and manufacturing processes, thereby reducing production costs.

It should be understood that in the present application, “arranged in the same layer” refers to a layer structure in which a layer for forming a specific pattern is formed by the same film forming process and then formed by one patterning process using the same mask. That is, one patterning process corresponds to a mask (also known as photomask). Depending on the specific graphics, one patterning process may include multiple exposure, development or etching processes, and the specific patterns in the formed layer structure may be continuous or discontinuous, and these specific patterns may also be at different heights or have different thicknesses, thus simplifying the manufacturing process, saving production costs and improving production efficiency.

It should be noted that the insulating barrier part 13 may be designed using different photomasks, which can be specifically designed according to different embodiments.

Referring to FIG. 1, in the embodiments of the present application, the insulating barrier part 13 includes a first portion 131 made of a metal material and a second portion 132 made of an insulating material, the first portion 131 is arranged on the side of the anti-view anode 121 away from the substrate 11, the anti-view light-emitting part 122 and the anti-view cathode 123 are both arranged around the first portion 131, and the first portion 131 removes the shielding effect of the anti-view cathode 123 and the anti-view light-emitting part 122 to ensure the normal signal transmission of the second electrode 142. The second portion 132 is arranged at a side of the first portion 131 away from the anti-view anode 121, and the orthographic projection of the second portion 132 on the substrate 11 covers the orthographic projection of the first portion 131 on the substrate 11. The second portion 132 is arranged between the first portion 131 and the touch electrode layer, which can shield the signal interference between the first portion 131 and the touch electrode layer and ensure the normal signal transmission of the second electrode 142.

It is worth mentioning that the first via hole 15 is provided in the overlapping area of the first portion 131 and the second portion 132, so as to ensure that the first portion 131 can effectively remove the shielding effect of the anti-view cathode 123 and ensure the normal signal transmission of the second electrode 142.

Referring to FIG. 1, in the embodiments of the present application, in the direction from the substrate 11 to the anti-view anode 121, the width of the first portion 131 and the width of the second portion 132 gradually decrease, and the opening area of the anti-view opening gradually increases. The enlarged anti-view opening and the width of the first portion 131 and the second portion 132 are gradually reduced so that the light brightness of the anti-view light-emitting part 122 can be improved and the anti-view effect can be ensured.

The method of manufacturing the touch display panel 10 includes the following steps:
S10. forming a drive backplane 18 on the substrate 11;
S20. forming an anti-view anode 121 and a display anode 161 on a side of the drive backplane 18 away from the substrate 11, and connecting to a source or drain of a thin film transistor on the drive backplane 18 through an opening;
S30. forming a pixel define layer 101 on a side of the drive backplane 18 away from the substrate 11, the pixel define layer 101 covering parts of the anti-view anode 121 and the display anode 161, and forming a display opening and an anti-view opening between adjacent pixel define layers 101;
S40. forming an insulating barrier 13 at an intermediate position of the anti-view opening;
S50. forming an anti-view light-emitting part 122 and a display light-emitting part 162 in the anti-view opening and the display opening, respectively;
S60. forming an anti-view cathode 123 on the anti-view light-emitting part 122, the display light-emitting part 162, and the pixel define layer 101, and removing the anti-view cathode 123 on the insulating barrier part 13 by etching to remove the shielding effect of the anti-view cathode 123;
S70. forming an encapsulation layer 19 on the anti-view cathode 123;
S80. providing a first via hole 15 on either of the encapsulation layer 19 and the insulating barrier part 13 to expose part of the anti-view anode 121;
S90. forming a touch electrode layer on the encapsulation layer 19, and the connecting part 1422 of the second electrode 142 being electrically connected to the anti-view anode 121 through the first via hole 15 to electrically connect the adjacent second electrodes 142; and
S100. forming a color resistance layer and a cover plate layer on the touch electrode layer.

By using the anti-view anode 121 as the bridging metal layer of the second electrode 142, the manufacturing processes of the metal layer and the number of photomasks are reduced, thereby reducing the production cost.

### Embodiment II

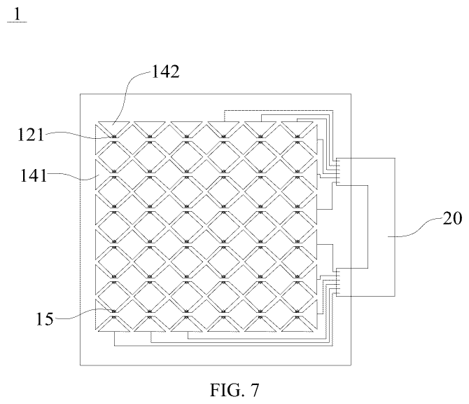

Referring to FIG. 7, Embodiment II of the present application provides a touch display device 1, which includes a flexible printed circuit board 20 and a touch display panel 10 in Embodiment I. Each first electrode 141 or second electrode 142 is formed by electrically connecting a plurality of electrode blocks arranged in a certain direction to each other. Each first electrode 141 or second electrode 142 is electrically connected to the flexible printed circuit board 20 as a channel through a signal line. The flexible printed circuit board 20 is provided with a chip. During the operation of the touch electrode, the chip can periodically provide driving signals to the second electrode 142 (driving electrode) in turn, and the chip receives an induction signal generated by capacitive coupling on the first electrode 141 (inducting electrode) to determine the touch position, thereby implements the touch function.

By multiplexing the anti-view anode 121 into the bridging metal layer of the second electrode 142, the manufacturing processes of the metal layer and the number of photomasks are reduced, thereby reducing the production cost.

In the content of the description, illustrations of the reference terms “some embodiments,” “example,” etc. mean that specific features, structures, materials, or characteristics described in connection with the embodiment or example are encompassed in at least one embodiment or example of the present application. In this description, the schematic formulation of the above terms need not be directed to the same embodiments or examples. Further, the specific features, structures, materials or characteristics described may be combined in a suitable manner in any one or more embodiments or examples. Further, without contradicting one another, those skilled in the art may combine and incorporate different embodiments or examples described in the description and features of different embodiments or examples.

Although embodiments of the present application have been shown and described above, it will be understood that the above-mentioned embodiments are exemplary and cannot be construed as limiting the present application. Those of ordinary skill in the art may make changes, variations, alternatives and modifications to the above-mentioned embodiments within the scope of the present application. Therefore, any changes or modifications made in accordance with the claims and descriptions of the present application should fall within the scope of the patent of the present application.

What is claimed is:

1. A touch display panel comprising a substrate provided with a touch anti-view area, wherein the touch anti-view area is provided with:
an anti-view sub-pixel comprising an anti-view anode, an anti-view light-emitting part and an anti-view cathode stacked sequentially;
an insulating barrier part formed on a side of the anti-view anode away from the substrate, wherein the insulating barrier part is provided with a first via hole, wherein a part of the anti-view anode is exposed though the first via hole, and a gap is formed between the first via hole and the anti-view cathode; and
a touch electrode layer comprising a first electrode and a second electrode alternately arranged in a first direction and insulated from each other, wherein the second electrode comprises a main electrode part and a connecting part, wherein the main electrode part of the second electrode and the first electrode are formed on a side of the anti-view sub-pixel away from the substrate and on a side of the insulating barrier part away from the substrate, wherein the connecting part of each second electrode is located in the first via hole and connected with the anti-view anode, and two adjacent second electrodes in the first direction are electrically connected through the anti-view anode.

2. The touch display panel according to claim 1, wherein the touch display panel further comprises a pixel define layer, the pixel define layer being formed on the substrate and located on the side of the anti-view anode away from the substrate, wherein in the touch anti-view area: the pixel define layer is provided with an anti-view opening to expose the anti-view anode, and the insulating barrier part is located in the anti-view opening and arranged in a same layer as the pixel define layer.

3. The touch display panel according to claim 1, wherein the anti-view light-emitting part and the anti-view cathode are arranged around the insulating barrier part.

4. The touch display panel according to claim 3, wherein the insulating barrier part comprises a first portion and a second portion, wherein the first portion is arranged on the side of the anti-view anode away from the substrate, and the anti-view light-emitting part and the anti-view cathode are arranged around the first portion, wherein the second portion is arranged on a side of the first portion away from the anti-view anode, and an orthographic projection of the second portion on the substrate covers an orthographic projection of the first portion on the substrate.

5. The touch display panel according to claim 4, wherein in a direction from the substrate to the anti-view anode:
a width of the first portion and a width of the second portion gradually decrease.

6. The touch display panel according to claim 2, wherein the touch display panel further comprises an encapsulation layer, wherein the encapsulation layer is arranged at a side of the anti-view cathode away from the anti-view anode, and the touch electrode layer is arranged in the encapsulation layer or at a side of the encapsulation layer away from the anti-view anode.

7. The touch display panel according to claim 1, wherein the substrate is further provided with display pixel areas, wherein the display pixel areas are arranged in an array on the substrate, and the anti-view sub-pixel is arranged between adjacent display pixel areas.

8. The touch display panel according to claim 7, wherein each of the display pixel areas is provided with a plurality of display sub-pixels spacing from each other, the anti-view sub-pixel is extended in a column direction, and a plurality of anti-view sub-pixels are arranged sequentially in a row direction, wherein anti-view anodes of adjacent anti-view sub-pixels are connected with display anodes of the plurality of display sub-pixels with different display colors.

9. The touch display panel according to claim 8, wherein the touch display panel further comprises a color resistance layer, wherein the color resistance layer comprises a color resistance element corresponding to each display anode of each display sub-pixel and a light-shielding element corresponding to the anti-view anode, wherein an orthographic projection of the light-shielding element on the substrate covers an orthographic projection of the anti-view anode on the substrate.

10. The touch display panel according to claim 8, wherein one of the first electrode and the second electrode is an induction electrode, and another of the first electrode and the second electrode is a driving electrode, wherein an orthographic projection of the driving electrode on the substrate is located in the orthographic projection of the anti-view anode on the substrate.

11. A touch display device comprising a flexible printed circuit board and a touch display panel, wherein the flexible printed circuit board is electrically connected to a first electrode and a second electrode;
wherein the touch display panel comprising a substrate provided with a touch anti-view area, wherein the touch anti-view area is provided with:
an anti-view sub-pixel comprising an anti-view anode, an anti-view light-emitting part and an anti-view cathode stacked sequentially;
an insulating barrier part formed on a side of the anti-view anode away from the substrate, wherein the insulating barrier part is provided with a first via hole, wherein a part of the anti-view anode is exposed though the first via hole, and a gap is formed between the first via hole and the anti-view cathode; and
a touch electrode layer comprising the first electrode and the second electrode alternately arranged in a first direction and insulated from each other, wherein the second electrode comprises a main electrode part and a connecting part, wherein the main electrode part of the second electrode and the first electrode are formed on a side of the anti-view sub-pixel away from the substrate and on a side of the insulating barrier part away from the substrate, wherein the connecting part of each second electrode is located in the first via hole and connected with the anti-view anode, and two adjacent second electrodes in the first direction are electrically connected through the anti-view anode.

12. The touch display device according to claim 11, wherein the touch display panel further comprises a pixel define layer, the pixel define layer being formed on the substrate and located on the side of the anti-view anode away from the substrate, wherein in the touch anti-view area: the pixel define layer is provided with an anti-view opening to expose the anti-view anode, and the insulating barrier part is located in the anti-view opening and arranged in a same layer as the pixel define layer.

13. The touch display device according to claim 11, wherein the anti-view light-emitting part and the anti-view cathode are arranged around the insulating barrier part.

14. The touch display device according to claim 13, wherein the insulating barrier part comprises a first portion and a second portion, wherein the first portion is arranged on the side of the anti-view anode away from the substrate, and the anti-view light-emitting part and the anti-view cathode are arranged around the first portion, wherein the second portion is arranged on a side of the first portion away from the anti-view anode, and an orthographic projection of the second portion on the substrate covers an orthographic projection of the first portion on the substrate.

15. The touch display device according to claim 14, wherein in a direction from the substrate to the anti-view anode:
a width of the first portion and a width of the second portion gradually decrease.

16. The touch display device according to claim 12, wherein the touch display panel further comprises an encapsulation layer, wherein the encapsulation layer is arranged at a side of the anti-view cathode away from the anti-view anode, and the touch electrode layer is arranged in the encapsulation layer or at a side of the encapsulation layer away from the anti-view anode.

17. The touch display device according to claim 11, wherein the substrate is further provided with display pixel areas, wherein the display pixel areas are arranged in an array on the substrate, and the anti-view sub-pixel is arranged between adjacent display pixel areas.

18. The touch display device according to claim 17, wherein each of the display pixel areas is provided with a plurality of display sub-pixels spacing from each other, the anti-view sub-pixel is extended in a column direction, and a plurality of anti-view sub-pixels are arranged sequentially in a row direction, wherein anti-view anodes of adjacent anti-view sub-pixels are connected with display anodes of the plurality of display sub-pixels with different display colors.

19. The touch display device according to claim 18, wherein the touch display panel further comprises a color resistance layer, wherein the color resistance layer comprises a color resistance element corresponding to each display anode of each display sub-pixel and a light-shielding element corresponding to the anti-view anode, wherein an orthographic projection of the light-shielding element on the substrate covers an orthographic projection of the anti-view anode on the substrate.

20. The touch display device according to claim 18, wherein one of the first electrode and the second electrode is an induction electrode, and another of the first electrode and the second electrode is a driving electrode, wherein an orthographic projection of the driving electrode on the substrate is located in the orthographic projection of the anti-view anode on the substrate.
